(19) United States
(12) Patent Application Publication
(10) Pub. No.: US 2024/0188222 A1
(43) Pub. Date: Jun. 6, 2024

(54) METHOD OF FORMING A PACKAGE SUBSTRATE

(71) Applicant: Intel Corporation, Santa Clara, CA (US)

(72) Inventors: Rahul MANEPALLI, Chandler, AZ (US); Srinivas PIETAMBARAM, Chandler, AZ (US); Darko GRUJICIC, Chandler, AZ (US); Marcel WALL, Phoenix, AZ (US); Jason STEILL, Phoenix, AZ (US)

(21) Appl. No.: 18/060,595

(22) Filed: Dec. 1, 2022

(51) Int. Cl. H05K 3/22; H05K 1/03; H05K 1/11; H05K 3/00

(52) U.S. Cl. CPC H05K 3/225; H05K 1/0306; H05K 1/115; H05K 3/002; H05K 3/0029; H01L 21/486

(57) ABSTRACT

The present disclosure is directed to a method providing a substrate core having a glass core layer with top and bottom surfaces and a build-up process performing operations to form a plurality of through-glass vias formed through the glass core layer and a plurality of conductive layers on the top and bottom surfaces of the glass core layer. As an integral part of the build-up process, a defect detection method may be used to detect defects in the glass core layer. The inspection for defects may be performed after selected operations. After one or more defect (e.g., crack) is uncovered, a repair process may be performed to repair the defects in the glass core layer. The repair of a defect may be performed immediately upon detection or after selected operations as a comprehensive repair of a group of defects.

### BACKGROUND

For integrated circuit design and fabrication, the need to improve performance and lower costs are constant challenges. As transistors continue to shrink in size and die become larger due to increased functionalities, it is becoming more and more difficult and costly to realize high-volume manufacturing for semiconductors. Cost savings may be potentially realized by building dies on substrate panels rather than semiconductor wafers. By using a rectangular panel as a carrier or substrate, panel-level fan-out technology, which uses a molded embedded design, offers the potential for lower production cost due to a higher area utilization ratio of the carrier and better economical manufacturing, especially for large heterogenous packages. Heterogeneous integration allows the stacking of dissimilar chips with different functions to be integrated within a package using lateral connections (2.5D embedded multi-die interconnect bridge (EMIB)) or vertical connections (3D) structure.

However, it is becoming more evident that manufacturing these types of packages may require a rigid carrier, such as glass, and the use of glass as a carrier may require the use of temporary bonding and debonding technology. One of the challenges associated with the temporary bonding and debonding technology is the warpage and shrinkage control post-removal of the rigid glass carrier. The package substrates may warp due to inbuilt residual stress and possible coefficient of thermal expansion mismatches between the various package components.

In addition, there may be physical strains and stress-induced defects caused by the handling of the package substrates by processing tools, which may render processing operations for thin package substrates extremely difficult to control and may result in low yields. It is therefore important to have panel-level package solutions that do not rely on temporary glass carriers and are able to maintain a high degree of rigidity and avoid excessive warpage along with other requirements.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1 and 1A show an exemplary representation of a glass panel with cracks at the edge portions according to an aspect of the present disclosure;

FIGS. 2A and 2B show exemplary representations of repaired cracks along an edge of a semiconductor panel according to an aspect of the present disclosure;

FIGS. 3A, 3B, 3C, and 3D show an exemplary representation of different stages of a package substrate assembly according to an aspect of the present disclosure;

FIG. 4 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure provides a solution that uses a glass core (e.g., monolithic glass) as a permanent core material in an organic substrate package to enable 2.5-D and 3-D heterogeneous integration and that provides edge “healing” or repair of panel-level or unit-level defects (e.g., cracks) in the glass core, thereby improving the glass core substrate yields. In an aspect, it is expected as of the present method to perform single and/or multiple panel edge healing or repair steps to enable successful glass core substrate processing through the line. The edge repair may be done at a unit level before singulation so that the substrates do not crack during the assembly process. In another aspect, the repair or healing process may be achieved through a wet treatment to slowly etch the edges and blunt the cracks to prevent crack propagation and panel/unit loss. Alternatively, the repair process may be a dry treatment using a laser, which can melt and fuse the cracks.

The present disclosure is directed to a method that includes providing a package substrate having a glass core layer with top and bottom surfaces. A substrate manufacturing process includes performing operations to form a plurality of through-glass vias formed through the glass core layer and a plurality of conductive layers on the top and bottom surfaces of the glass core layer. As an integral part of the build-up process, a defect detection method may be used to detect defects in the glass core layer. The inspection for defects may be performed after selected operations. After one or more defect (e.g., crack) is uncovered, a repair process may be performed to repair the defects in the glass core layer. The repair of a defect may be performed immediately upon detection or after selected operations as a comprehensive repair of a group of defects.

In another aspect, the present disclosure is directed to a package substrate that includes a substrate with a glass core layer having top and bottom surfaces, a plurality of through-glass vias formed through the glass core layer, a plurality of conductive layers formed on the top and bottom surfaces of the glass core layer, and one or more repaired defects, e.g., fused and/or blunted cracks, located in the glass core layer at its edge portions.

In yet another aspect, the present disclosure is directed to a method that includes providing a glass substrate core and performing a build-up process using the glass substrate core to form a package substrate. In an aspect, the build-up process causes stress-induced cracks in the glass substrate core, and a defect detection method is used to detect stress-induced cracks located at edge portions of the glass substrate core. In a further aspect, the method includes operations to repair the stress-induced cracks located at edge portions of the glass substrate core.

The technical advantages of the present disclosure include, but are not limited to:
(i) Providing a rigid glass core layer as a core for a package substrate;
(ii) Providing processes for the detection and repair of cracks to prevent the propagation of the defects; and
(iii) Providing package substrates for panel-level and unit-level high-volume manufacturing and methods for improving yields.

To more readily understand and put into practical effect the present method for repairing package substrates, which may be used for panel-level substrate manufacturing to improve yield and performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

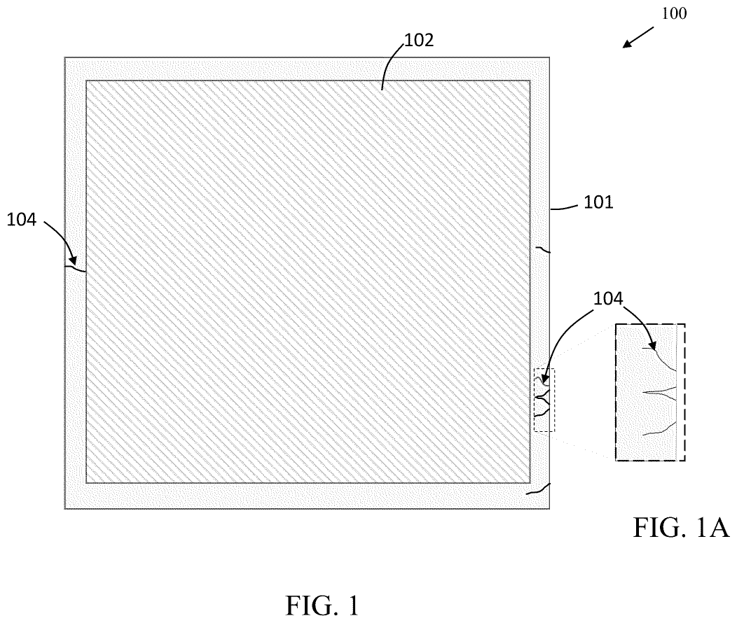

In FIG. 1, an exemplary representation of a glass panel 100 having a non-active border area or keep-out zone 101 and an active area 102 according to an aspect of the present disclosure. The non-active area or keep-out zone 101 may have a plurality of defects or cracks 104 at the edge portion of the non-active area 101. As shown in FIG. 1A, an exemplary expanded view of a section of the keep-out zone of the semiconductor panel 100 provides a further view of the cracks 104. The cracks 104 may affect the structural integrity of the glass panel 100 and propagate and grow into the active area 102 if left unrepaired, which may render sections or the whole of the glass panel 100 unusable.

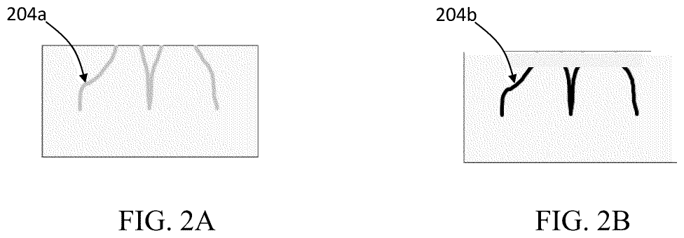

FIGS. 2A and 2B show exemplary representations of repaired cracks along an edge of a semiconductor panel according to an aspect of the present disclosure. In FIG. 2A, the cracks 204a have been repaired by a dry treatment, i.e., using a laser healing process, that applies heat to the cracks and at least partially fuses the crack 204a. It should be understood that a laser with an appropriate energy level may need to be selected, and lasers, such as ultraviolet (UV), infrared (IR or carbon dioxide (CO2) lasers may be used to achieve the repair. In addition, a dry treatment may include a reactive ion etching process that can selectively etch away the defects.

In FIG. 2B, the cracks 204b have been repaired by a wet treatment, i.e., using an acid or basic solution etching process, that applies chemicals to the cracks and at least partially blunts the cracks 204b. For example, the wet etching solutions may be hydrofluoric acid (5-10%) solutions or sodium or potassium hydroxide (up to 50%) solutions, which are well-known glass etching solutions. In an aspect, the blunted or fused cracks at the edge of a unit will be present in the final package and may be easily detectable by visual inspection or a low-magnification optical microscope.

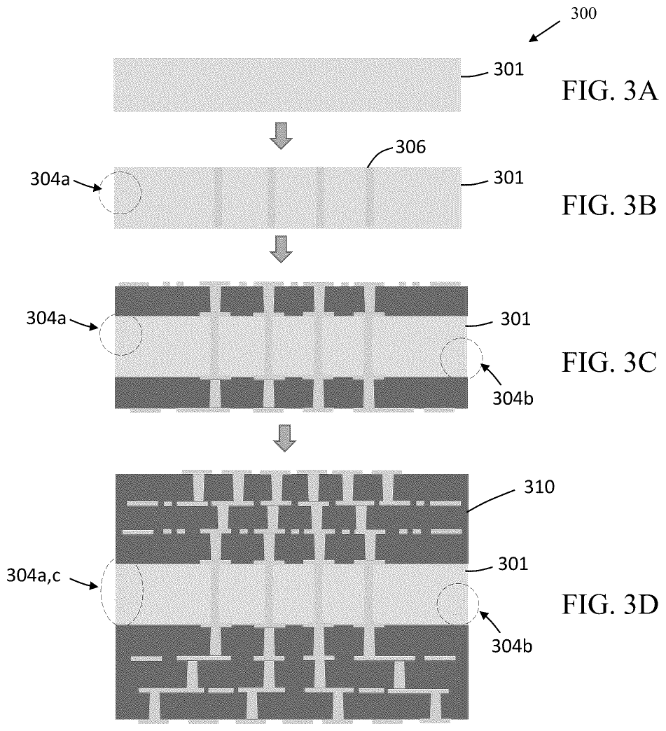

FIGS. 3A, 3B, 3C, and 3D show an exemplary representation of different intermediate stages of a package substrate build-up process 300 according to an aspect of the present disclosure. It is within the scope of the present disclosure to select and employ conventional process steps, tools, and methods in the build-up process. In FIG. 3A, a glass core 301, which may be a monolithic glass core layer, is shown. In FIG. 3B, a plurality of through-glass vias 306 may be formed in the glass core 301 as shown. In an aspect, at this juncture of the substrate manufacturing process 300, a defect detection process may be performed using a conventional metrology tool, such as an automated optical inspection (AOI) tool. During the formation of the plurality of through-glass vias 306, the defects 304a may be formed due to handing by the processing equipment. The defects 304a may be repaired immediately or repaired as a group after a threshold for the defects is reached. In FIG. 3C, the substrate manufacturing process 300 provides additional conductive layers and interconnects, and defects 304b may be produced.

In an aspect, at this juncture of the substrate manufacturing 300, a second defection detection process may be performed using a conventional metrology tool, such as an AOI tool. The defects 304b may be repaired immediately or repaired as a group after a threshold for the defects is reached. In FIG. 3D, the assembly process 300 may provide additional conductive layers and interconnects to form a completed package substrate 310 and there may be detected and repaired defects 304a, 304b, and 304c as shown. It should be understood that the present defect detection process and the defect repair or healing steps may be performed as often as needed during a substrate manufacturing process. In another aspect, the operations to form conductive layers on the top may include forming a multi-chip interconnect bridge (not shown) in the conductive layers.

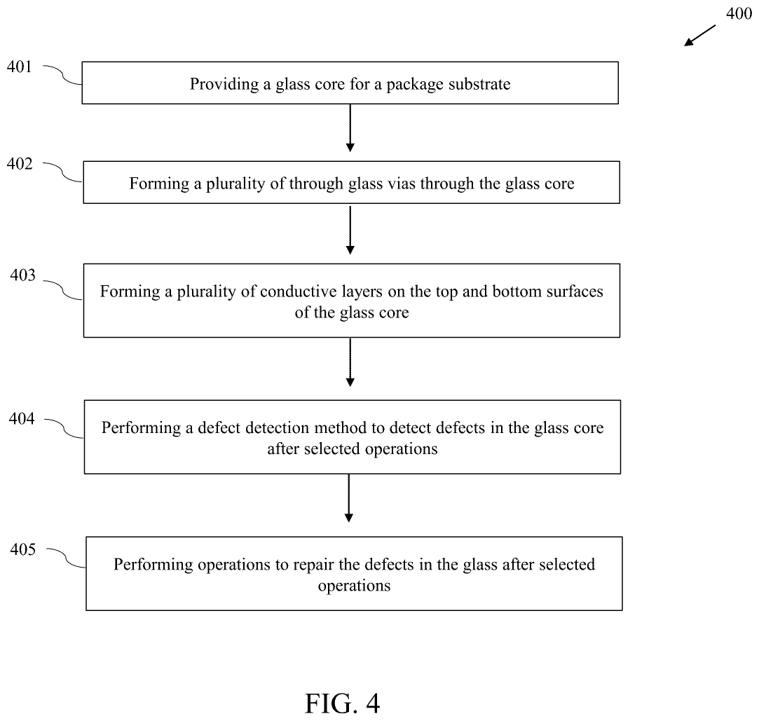

FIG. 4 shows a simplified flow diagram for an exemplary method 400 according to an aspect of the present disclosure.

The operation 401 may be directed to providing a glass core for a package substrate.

The operation 402 may be directed to forming a plurality of through glass vias through the glass core.

The operation 403 may be directed to forming a plurality of conductive layers on the top and bottom surfaces of the glass core.

The operation 404 may be directed to performing a defect detection method to detect defects in the glass core after selected operations.

The operation 405 may be directed to performing operations to repair the defects in the glass after selected operations.

It will be understood that any property described herein for a specific package substrate with a rigid glass core may also hold for any package substrate described herein. It will also be understood that any property described herein for a specific method may hold for any of the methods described herein. Furthermore, it will be understood that for any package substrate and the methods described herein, not necessarily all the components or operations described will be shown in the accompanying drawings or method, but only some (not all) components or operations may be disclosed.

To more readily understand and put into practical effect the present semiconductor carrier platforms and thermal stability layers, they will now be described by way of examples. For the sake of brevity, duplicate descriptions of features and properties may be omitted.

### Examples

Example 1 provides a method including providing a substrate core comprising a glass core layer with top and bottom surfaces, performing operations to form a plurality of through-glass vias formed through the glass core layer, performing operations to form a plurality of conductive layers on the top and bottom surfaces of the glass core layer, performing a defect detection method to detect defects in the glass core layer, for which the defect detection method is performed after selected operations, and performing operations to repair the defects in the glass core layer, for which the repair of the defect is performed after selected operations.

Example 2 may include the method of example 1 and/or any other example disclosed herein, for which the defect detection is directed to locating cracks at the edge portions of the glass core layer.

Example 3 may include the method of example 1 and/or any other example disclosed herein, for which the operations to repair the defect comprises a wet treatment.

Example 4 may include the method of example 3 and/or any other example disclosed herein, for which the wet treatment includes etching with an acid solution to fuse or blunt the defects.

Example 5 may include the method of example 3 and/or any other example disclosed herein, for which the wet treatment includes etching with a basic solution to fuse or blunt the defects.

Example 6 may include the method of example 1 and/or any other example disclosed herein, for which the operations to repair the defect comprises a dry treatment.

Example 7 may include the method of example 6 and/or any other example disclosed herein, for which the dry treatment includes irradiating the defects with a laser beam to fuse or blunt the defects.

Example 8 may include the method of example 1 and/or any other example disclosed herein, for which the defect detection is performed after forming the through glass vias.

Example 9 may include the method of example 8 and/or any other example disclosed herein, for which the performing operations to form a plurality of conductive layers on the top and bottom surfaces of the glass core layer further includes forming a multi-chip interconnect bridge in the plurality of conductive layers.

Example 10 provides a package substrate that includes a substrate core having a glass core layer with top and bottom surfaces, a plurality of through-glass vias formed through the glass core layer, a plurality of conductive layers formed on the top and bottom surfaces of the glass core layer, and one or more repaired defects located in the glass core layer.

Example 11 may include the package substrate of example 10 and/or any other example disclosed herein, for which one or more repaired defects includes one or more blunted or fused cracks.

Example 12 may include the package substrate of example 10 and/or any other example disclosed herein, for which the one or more repaired defects are located at edge portions of the glass core layer.

Example 13 may include the package substrate of example 10 and/or any other example disclosed herein, for which the glass core layer includes a monolithic or a laminated glass core layer.

Example 14 provides a method that provides a glass core substrate, performing a build-up process using the glass core substrate to form a package substrate, for which the build-up process causes stress-induced cracks in the glass core substrate, performing a defect detection method to detect stress-induced cracks located at edge portions of the glass core substrate, and performing operations to repair the stress-induced cracks located at edge portions of the glass core substrate.

Example 15 may include the method of example 14 and/or any other example disclosed herein, for which the defect detection method and/or the repair of the stress-induced cracks are repeatedly performed, for which the repair operations fuses or blunts the stress-induced cracks located at edge portions of the glass substrate core.

Example 16 may include the package substrate of example 14 and/or any other example disclosed herein, for which the stress-induced cracks are caused by mismatches in the coefficient of thermal expansion of components of an assembled semiconductor package.

Example 17 may include the package substrate of example 15 and/or any other example disclosed herein, for which the repair operations comprise wet and/or dry treatments to fuse or blunt the defects.

Example 18 may include the package substrate of example 17 and/or any other example disclosed herein, for which the wet treatments comprise etching with an acidic or basic solution to fuse or blunt the defects.

Example 19 may include the package substrate of example 17 and/or any other example disclosed herein, for which the dry treatment comprises irradiating the defects with a laser beam to fuse or blunt the defects.

Example 20 may include the package substrate of example 14 and/or any other example disclosed herein, for which the build-up process comprises forming a plurality of conductive layers on a top surface and a bottom surface of the glass core layer.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A method comprising:
providing a substrate comprising a glass core layer with top and bottom surfaces;
performing operations to form a plurality of through-glass vias formed through the glass core layer;
performing operations to form a plurality of conductive layers on the top and bottom surfaces of the glass core layer;
performing a defect detection method to detect defects in the glass core layer, wherein the defect detection method is performed after selected operations; and
performing operations to repair the defects in the glass core layer, wherein the repair of the defect is performed after selected operations.

2. The method of claim 1, wherein the defect detection is directed to locating cracks at the edge portions of the glass core layer.

3. The method of claim 1, wherein the operations to repair the defect comprises a wet treatment.

4. The method of claim 3, wherein the wet treatment comprises etching with an acid solution to fuse or blunt the defects.

5. The method of claim 3, wherein the wet treatment comprises etching with a basic solution to fuse or blunt the defects.

6. The method of claim 1, wherein the operations to repair the defect comprises a dry treatment.

7. The method of claim 6, wherein the dry treatment comprises irradiating the defects with a laser beam to fuse or blunt the defects.

8. The method of claim 1, wherein the defect detection is performed after forming the through glass vias.

9. The method of claim 1, wherein the performing operations to form a plurality of conductive layers on the top and bottom surfaces of the glass core layer further comprises forming a multi-chip interconnect bridge in the plurality of conductive layers.

10. A package substrate comprising:
a substrate comprising a glass core layer with top and bottom surfaces;
a plurality of through-glass vias formed through the glass core layer;
a plurality of conductive layers formed on the top and bottom surfaces of the glass core layer; and
one or more repaired defects located in the glass core layer.

11. The package substrate of claim 10, wherein the one or more repaired defects comprises one or more blunted or fused cracks.

12. The package substrate of claim 10, wherein the one or more repaired defects are located at edge portions of the glass core layer.

13. The package substrate of claim 10, wherein the glass core layer comprises a monolithic glass core layer.

14. A method comprising:
providing a glass core substrate;
performing a build-up process using the glass core substrate to form a package substrate, wherein the build-up process causes stress-induced cracks in the glass core substrate;
performing a defect detection method to detect stress-induced cracks located at edge portions of the glass core substrate; and
performing operations to repair the stress-induced cracks located at edge portions of the glass core substrate.

15. The method of claim 14, wherein the defect detection method and/or the repair of the stress-induced cracks are repeatedly performed, wherein the repair operations fuses or blunt the stress-induced cracks located at edge portions of the glass substrate core.

16. The method of claim 14, wherein the stress-induced cracks are caused by mismatches in coefficients of thermal expansion of components of an assembled semiconductor package.

17. The method of claim 14, wherein the repair operations comprise wet and/or dry treatments to fuse or blunt the defects.

18. The method of claim 17, wherein the wet treatments comprise etching with an acidic or basic solution to fuse or blunt the defects.

19. The method of claim 17, wherein the dry treatment comprises irradiating the defects with a laser beam to fuse or blunt the defects.

20. The method of claim 14, wherein the build-up process comprises forming a plurality of conductive layers on a top surface and a bottom surface of the glass core layer.
